(19) United States
(12) Patent Application Publication
(10) Pub. No.: US 2025/0219606 A1
(43) Pub. Date: Jul. 3, 2025

(54) SIGNAL TRANSMISSION CIRCUIT AND ELECTRONIC DEVICE

(71) Applicant: Panasonic Automotive Systems Co., Ltd., Kanagawa (JP)

(72) Inventors: Shunsuke KATSUMURA, Tokyo (JP); Tatsuya INOUE, Osaka (JP); Hideaki TOKUNAGA, Osaka (JP); Keiji KOBAYASHI, Osaka (JP); Kenji NOZOE, Fukui (JP)

(21) Appl. No.: 18/954,142

(22) Filed: Nov. 20, 2024

(30) Foreign Application Priority Data
Dec. 27, 2023 (JP) 2023-220285

(51) Int. Cl. H03H 7/01; H01P 3/06

(52) U.S. Cl. CPC H03H 7/0115; H01P 3/06

(57) ABSTRACT

A signal transmission circuit includes: a common mode filter including a first inductor and a second inductor; first and second circuits including capacitors and having a same circuit configuration; a third circuit including an input end and an output end, has a circuit configuration different from the second circuit, reflecting a predetermined amount of a signal in a predetermined frequency band including a frequency of a transmission signal; first and second transmission lines connected to a communication circuit outputting a differential signal, and connected to the first, second inductors via the first and second circuits, the second transmission line having characteristic impedance different from the third circuit; a third transmission line connected to the first inductor and an output terminal; a fourth transmission line connected to the second inductor and the input end; and a fifth transmission line connected to the output end and a ground or an earth.

### CROSS-REFERENCE TO RELATED APPLICATIONS

This application is based upon and claims the benefit of priority from Japanese Patent Application No. 2023-220285, filed on Dec. 27, 2023, the entire contents of which are incorporated herein by reference.

### FIELD

The present disclosure relates to a signal transmission circuit and an electronic device.

### BACKGROUND

JP 2019-536300 W discloses a transmission circuit that includes a common mode filter (common mode choke) including two input connection sections and two output connection sections and transmits a signal via a coaxial cable. Patent Literature 1 discloses that one of the two output connection sections is connected to the coaxial cable and the other is connected to a chassis via series connection of a resistor and a capacitor.

There is a demand for improving the strength of a signal to be transmitted.

### SUMMARY

A signal transmission circuit according to the present disclosure includes a first circuit, a second circuit, a third circuit, a first transmission line, a second transmission line, a third transmission line, a fourth transmission line, and a fifth transmission line. The common mode filter includes a first inductor and a second inductor. The first circuit includes a first capacitor. The second circuit includes a second capacitor and has a same circuit configuration as the first circuit. The third circuit includes an input end and an output end, has a circuit configuration different from the second circuit, reflects a predetermined amount of a signal in a predetermined frequency band including a frequency of a transmission signal in a signal input thereto, and allows another component to pass. The first transmission line has one end connected to a communication circuit that outputs a differential signal, and has another end connected to one end of the first inductor via the first circuit. The second transmission line has one end connected to the communication circuit, and has the other end connected to one end of the second inductor via the second circuit and having characteristic impedance different from impedance of the third circuit. The third transmission line is connected to another end of the first inductor and an output terminal. The fourth transmission line is connected to another end of the second inductor and the input end. The fifth transmission line is connected to the output end and a ground or an earth.

### BRIEF DESCRIPTION OF THE DRAWINGS

FIG. 1 is a schematic diagram of a configuration of an electronic device according to a first embodiment;

FIG. 2 is a diagram illustrating an example of a simulation result of impedance in a third circuit of a signal transmission circuit according to the first embodiment;

FIG. 3 is a reference example of a configuration of an electronic device in which the feature in the present disclosure is not implemented;

FIG. 4 is a diagram illustrating an example of a simulation result of an eye pattern of a signal that passes through a coaxial cable in FIG. 3;

FIG. 5 is a diagram illustrating an example of a simulation result of an eye pattern of a signal that passes through the coaxial cable in FIG. 1;

FIG. 6 is a schematic diagram of a configuration of an electronic device according to a second embodiment;

FIG. 7 is a diagram illustrating an example of a simulation result of impedance in a fifth circuit of a signal transmission circuit according to the second embodiment; and

FIG. 8 is a diagram illustrating an example of a simulation result of an eye pattern of a signal that passes through a coaxial cable in FIG. 6.

### DETAILED DESCRIPTION

A signal transmission circuit according to the present disclosure is configured as follows. In the following explanation, the same or equivalent components, members, or steps illustrated in the drawings are denoted by the same reference numerals and signs and redundant explanation is omitted as appropriate. The dimensions of members in the drawings are enlarged or reduced as appropriate in order to facilitate understanding.

In the present specification, the expression “equal” includes a case in which two elements are not completely equal but can be regarded as substantially equal. That is, the expression “equal” includes a case in which two elements can be considered to be substantially equal, for example, a case in which the two elements are different by approximately several percent.

### First Embodiment

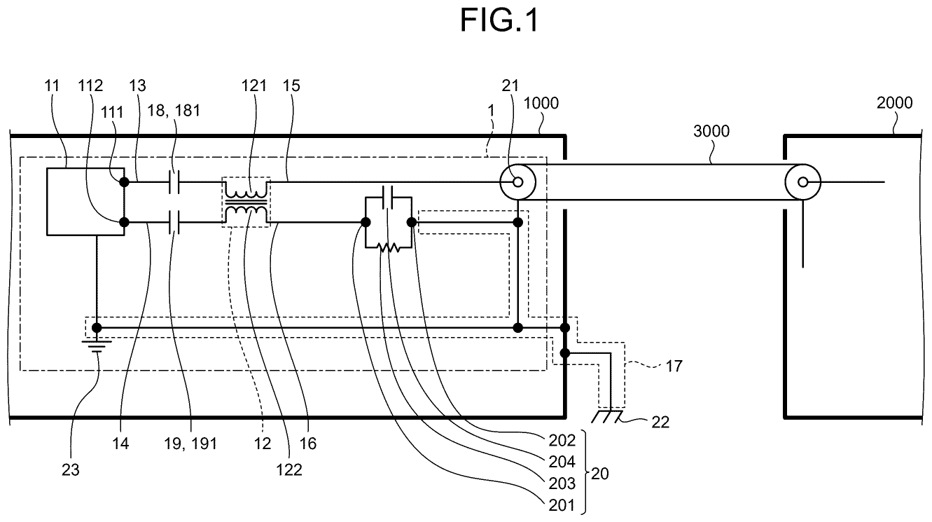

FIG. 1 is a schematic diagram of a configuration of an electronic device according to a first embodiment;

Note that, in FIG. 1, for easy understanding, in addition to an electronic device 1000, an electronic device 2000, which is a signal transmission target, and a coaxial cable 3000 are also illustrated.

As illustrated in FIG. 1, the electronic device 1000 is connected to the electronic device 2000 via the coaxial cable 3000. The electronic device 1000 and the electronic device 2000 are, for example, an in-vehicle device. The electronic device 1000 as the in-vehicle device is, for example, a vehicle-mounted camera that images the periphery of a vehicle.

The electronic device 2000 as an in-vehicle device is, for example, a display device. The electronic device 2000 is a display device mounted on the vehicle such as a car navigation system, a display audio system, and a monitor. The electronic device 2000 may be a display device that displays an image captured by the vehicle-mounted camera.

The electronic device 1000 includes a signal transmission circuit 1.

The signal transmission circuit 1 transmits a signal generated by the electronic device 1000 to the electronic device 2000 via the coaxial cable 3000. For example, when the electronic device 1000 is the vehicle-mounted camera, the signal transmission circuit 1 transmits a signal of an image captured by the electronic device 1000 to the electronic device 2000 via the coaxial cable 3000.

The signal transmission circuit 1 includes a common mode filter 12 including a first inductor 121 and a second inductor 122, a first transmission line 13, a second transmission line 14, a third transmission line 15, a fourth transmission line 16, a fifth transmission line 17, a first circuit 18, a second circuit 19, and a third circuit 20.

The signal transmission circuit 1 may include a communication circuit 11 and an output terminal 21. Since the signal transmission circuit 1 includes the communication circuit 11, the lengths of the first transmission line 13 and the second transmission line 14 can be reduced compared with when the communication circuit 11 is provided on the outside of the signal transmission circuit 1. Therefore, an attenuation amount of the energy of a signal flowing through the transmission lines can be reduced. It is possible to reduce a possibility that noise occurs in the signal flowing through the first transmission line 13 and the second transmission line 14.

Further, when the electronic device 1000 is the in-vehicle device, the electronic device 1000 may include a housing. The signal transmission circuit 1 may include a body ground 22 and a housing ground 23. The body ground 22 is a connection point between a vehicle body and the signal transmission circuit 1. The housing ground 23 is a connection point between the housing of the electronic device 1000 and the signal transmission circuit 1. Since the electronic device 1000 is stored in a non-conductive case, for example, a case made of resin, the signal transmission circuit 1 sometimes cannot be connected to the vehicle body. In that case, the signal transmission circuit 1 may not include the body ground 22.

In the following description, a case in which the signal transmission circuit 1 includes the communication circuit 11, the output terminal 21, the body ground 22, and the housing ground 23 is explained as an example.

The communication circuit 11 includes a first output node 111 and a second output node 112 and outputs a differential signal via the first output node 111 and the second output node 112.

One end of the first transmission line 13 is connected to the first output node 111 of the communication circuit 11. Accordingly, the communication circuit 11 outputs a first signal serving as the differential signal from the output node 111 to the first transmission line 13.

One end of the second transmission line 14 is connected to the second output node 112 of the communication circuit 11. Accordingly, the communication circuit 11 outputs a second signal serving as the differential signal from the second output node 112 to the second transmission line 14.

Here, the first signal and the second signal are high-frequency signals having phases opposite to each other. As an example, the signal transmission circuit 1 in the present embodiment transmits a high-frequency signal of 100 MHz or more.

The other end of the first transmission line 13 is connected to one end of the first inductor 121 via the first circuit 18. The first signal output from the first output node 111 is input to the first inductor 121 via the first transmission line 13. The first circuit 18 includes a first capacitor 181. The first circuit 18 may include only the first capacitor 181. The first capacitor 181 blocks a DC component of the DC component and an AC component included in the first signal. As an example, in the present embodiment, the capacitance of the first capacitor 181 is 100 nF.

The other end of the second transmission line 14 is connected to one end of the second inductor 122 via the second circuit 19. The second signal output from the second output node 112 is input to the second inductor 122 via the third transmission line 15. The first circuit 18 and the second circuit 19 have the same circuit configuration. The second circuit 19 includes a second capacitor 191. The second circuit 19 may include only the second capacitor 191. The second capacitor 191 blocks a DC component of the DC component and an AC component included in the second signal. As an example, in the present embodiment, the capacitance of the second capacitor 191 is 100 nF.

In the present embodiment, the first transmission line 13 and the second transmission line 14 are formed of, for example, a copper wire. The characteristic impedances of the first transmission line 13 and the second transmission line 14 are determined by, for example, the thickness of the copper wire.

Incidentally, when the characteristic impedance of the first transmission line 13 and the characteristic impedance of the second transmission line 14 are different, the waveforms of the first signal and the second signal change in a process of passing over the first transmission line 13 and the second transmission line 14. There is a possibility that the first signal and the second signal do not have the opposite phases. As a result, there is a possibility that common mode noise occurs in the first signal and the second signal.

However, in the present embodiment, both of the characteristic impedances of the first transmission line 13 and the second transmission line 14 are, for example, 50Ω. That is, the characteristic impedance of the first transmission line 13 and the characteristic impedance of the second transmission line 14 are equal. Accordingly, the signal transmission circuit 1 in the present embodiment can reduce the possibility that the common mode noise occurs in the first signal and the second signal.

The common mode filter 12 includes the first inductor 121 and the second inductor 122.

The first inductor 121 has one end connected to the first transmission line 13 and the other end connected to the third transmission line 15. The first signal is input to the first inductor 121 from the first transmission line 13. The first inductor 121 outputs a third signal, which is a signal based on the first signal, to the third transmission line 15.

The second inductor 122 has one end connected to the second transmission line 14 and the other end connected to the fourth transmission line 16. The second signal is input to the second inductor 122 from the second transmission line 14. The second inductor 122 outputs a fourth signal, which is a signal based on the second signal, to the fourth transmission line 16.

The common mode filter 12 is a filter that attenuates the common mode noise included in the input first signal and the input second signal and allows a component, which is not the common mode noise, to pass. That is, since the signal transmission circuit 1 includes the common mode filter 12, when the common mode noise has occurred in the first signal and the second signal, the signal transmission circuit 1 can reduce the common mode noise. When the common mode noise has occurred in the first signal and the second signal, the third signal is a signal obtained by attenuating the common mode noise included in the first signal and the fourth signal is a signal obtained by attenuating the common mode noise included in the second signal.

Therefore, when the common mode noise has not occurred in the first signal and the second signal, the first signal and the third signal are signals having the same waveform and the second signal and the fourth signal are signals having the same waveform.

The third transmission line 15 is connected to the other end of the first inductor 121 and the output terminal 21. The coaxial cable 3000 is connected to the output terminal 21. The third signal input from the first inductor 121 to the third transmission line 15 is output to the coaxial cable 3000 via the output terminal 21.

The third circuit 20 includes an input end 201 and an output end 202. The third circuit 20 has a circuit configuration different from the first circuit 18 and the second circuit 19. Specifically, the third circuit 20 may include a first resistor 203 and a third capacitor 204 connected to the first resistor 203 in parallel. As an example, in the present embodiment, the resistance value of the first resistor 203 is 50Ω and the capacitance of the third capacitor 204 is 10 pF. In the present embodiment, the characteristic impedance of the second transmission line 14 and the impedance of the third circuit 20 are different. The impedance of the third circuit 20 may be smaller or larger than the characteristic impedance of the second transmission line 14. In the present embodiment, the impedance of the third circuit 20 is smaller than the characteristic impedance of the second transmission line 14. Details of the impedance of the third circuit 20 is explained below.

The fourth transmission line 16 is connected to the other end of the second inductor 122 and the input end 201. The fourth transmission line 16 is preferably as short as possible. By shortening the fourth transmission line 16, it is possible to reduce a phase shift between a signal flowing from the other end of the second inductor 122 to the input end 201 and a signal reflected in a third circuit 20 explained below. When the second inductor 122 and the third circuit 20 can be directly connected, the fourth transmission line 16 can be omitted. A case in which the second inductor 122 and the third circuit 20 can be directly connected is, for example, a case in which respective surface mounting pads of the second inductor 122 and the third circuit 20 can be directly connected.

The fifth transmission line 17 is connected to the output end 202 and the ground or the earth. In the present embodiment, the fifth transmission line 17 is connected to the output end 202 and the ground. Here, the ground is the body ground 22 and the housing ground 23. As explained above, the signal transmission circuit 1 sometimes does not include the body ground 22. In that case, the ground is the housing ground 23.

Generally, when a signal is transmitted, since a part of the energy of the signal may be converted into other energy, such as heat, attenuation of the signal can occur. An attenuation amount of the signal is larger as the signal has a higher frequency. Therefore, for example, when a high-frequency signal is transmitted from the electronic device 1000 to the electronic device 2000 via the coaxial cable 3000, the energy of the third signal output from the electronic device 1000 can be attenuated before being input to the electronic device 2000. Depending on an attenuation amount of the energy of the third signal, it is likely that the strength of the third signal input to the electronic device 2000 falls below a threshold of the strength of a signal that can be detected by the electronic device 2000. As a result, there is a possibility that the electronic device 2000 cannot detect the signal.

In the signal transmission circuit 1 in the present embodiment, the third circuit 20 reflects a part of an input signal. Then, the signal reflected by the third circuit 20 is output from the electronic device 1000 via the third transmission line 15. Accordingly, the energy of the signal reflected by the third circuit 20 can be added to the third signal. As a result, it is possible to improve the strength of the signal output from the electronic device 1000. The principle by which the third circuit 20 reflects a part of the input signal is explained below.

First, the impedance of the third circuit 20 is explained.

The impedance of the third circuit 20 is determined by the resistance value of the first resistor 203, the capacitance of the third capacitor 204, and the frequency of a signal input to the third circuit 20. Here, the signal input to the third circuit 20 is the fourth signal.

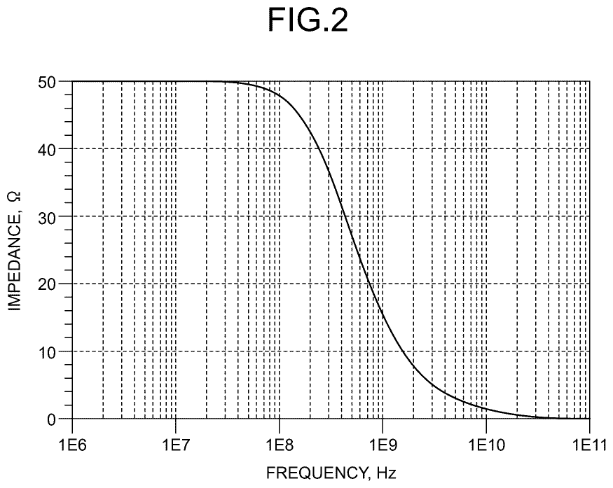

FIG. 2 is a simulation result indicating a relation between the frequency of a signal input to the third circuit 20 and the impedance of the third circuit 20 in the present embodiment.

In FIG. 2, the horizontal axis represents the frequency of the signal input to the third circuit 20 and the vertical axis represents the impedance of the third circuit 20.

According to FIG. 2, it is seen that the impedance of the third circuit 20 is lower as the frequency of the signal input to the third circuit 20 is higher.

According to FIG. 2, it can be seen that a decrease in the impedance of the third circuit 20 occurs when the frequency of the signal input to the third circuit 20 is higher than approximately several tens MHz.

Here, the frequency of the signal input to the third circuit 20 at the time when the decrease in the impedance of the third circuit 20 starts to occur is referred to as decrease start frequency. Further, when a signal having a frequency lower than the decrease start frequency is input, the impedance of the third circuit 20 coincides the resistance value of the first resistor 203. Therefore, as illustrated in FIG. 2 as well, the impedance of the third circuit 20 in the case in which the signal having the frequency lower than the decrease start frequency is input is 50Ω, which coincides the characteristic impedance of the second transmission line 14.

The decrease start frequency is determined by the resistance value of the first resistor 203 and the capacitance of the third capacitor 204. Here, in the present embodiment, in order to match the impedance of the third circuit 20 in the case in which the signal having the frequency lower than the decrease start frequency is input and the characteristic impedance of the second transmission line 14, the resistance value of the first resistor 203 is fixed to 50Ω. For that reason, when the decrease start frequency is changed, the capacitance of the third capacitor 204 is changed. That is, as the capacitance of the third capacitor 204 in the present embodiment is set larger than 10 pF, the decrease start frequency is smaller. As the capacitance of the third capacitor 204 is set smaller than 10 pF, the decrease start frequency is higher.

As explained above, in the present embodiment in which a high-frequency signal of 100 MHz or more is transmitted, the characteristic impedance of the second transmission line 14 is different from the impedance of the third circuit 20. Accordingly, reflection of a signal occurs in the third circuit 20. Specifically, the third circuit 20 reflects a part of an input signal and allows the other part to pass. Here, the signal input to the third circuit 20 is the fourth signal. That is, the third circuit 20 reflects a fifth signal, which is a part of the fourth signal, toward the second inductor 122 and allows a sixth signal, which is a signal other than the fifth signal, in the fourth signal to pass. The fifth signal is an example of a predetermined amount of a signal in a predetermined frequency band including a frequency of a transmission signal. The sixth signal having passed through the third circuit 20 flows to the body ground 22 and the housing ground 23.

The fifth signal reflected by the third circuit 20 is input to the second inductor 122. When the fifth signal is input to the second inductor 122, the energy of the fifth signal is transferred from the second inductor 122 to the first inductor 121 by mutual induction between the first inductor 121 and the second inductor 122 and a seventh signal is generated in the first inductor 121. The seventh signal is output from the first inductor 121 to the coaxial cable 3000 via the third transmission line 15 and the output terminal 21.

As explained above, in addition to the third signal, the seventh signal is also input to the third transmission line 15 and the coaxial cable 3000. As a result, it is possible to add the energy of the seventh signal to the third signal which is a high-frequency signal and in which the energy is attenuated when the signal is transmitted. For that reason, the strength of the signal output from the electronic device 1000 can be improved.

A reflection coefficient Γ representing a ratio of a signal reflected by the third circuit 20 is represented by the following expression using Z1, which is the characteristic impedance of the second transmission line 14, and Z2, which is the impedance of the third circuit 20.

$$Γ = ( Z 1 - Z 2 ) / ( Z 1 + Z 2 )$$

Therefore, in the present embodiment, as the difference between the characteristic impedance of the second transmission line 14 and the impedance of the third circuit 20 is larger, the reflection coefficient is larger. Therefore, an amount of the signal reflected by the third circuit 20 is larger. As illustrated in FIG. 2, as the frequency of the signal input to the third circuit 20 is higher, the impedance of the third circuit 20 more greatly decreases. Therefore, the difference between the impedance of the third circuit 20 and the characteristic impedance of the second transmission line 14 is also larger. As explained above, in the present embodiment, as the frequency of the signal to be transmitted is higher, the third circuit 20 can reflect a larger amount of a signal. Therefore, as the frequency of a signal to be transmitted is higher, larger energy (energy of the seventh signal) can be added to the third signal.

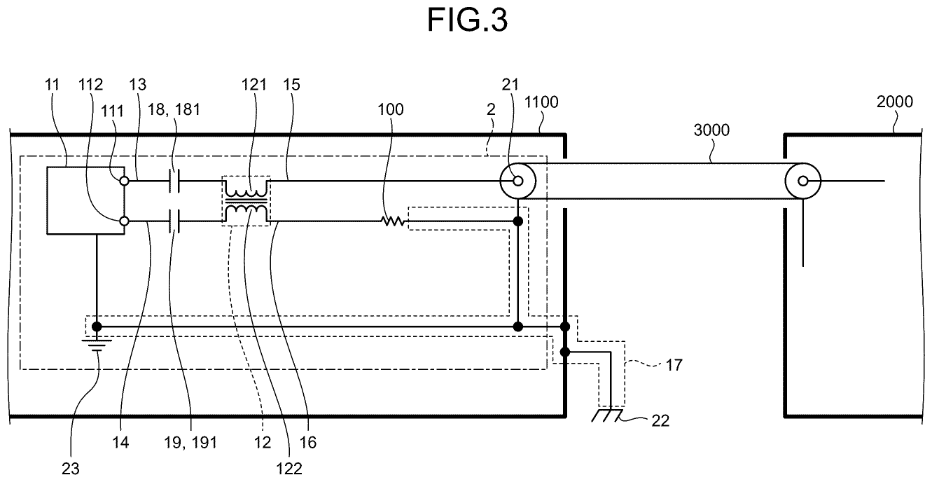

FIG. 3 is a schematic diagram of a reference example of the electronic device 1100 in which the feature in the present disclosure is not implemented.

A signal transmission circuit 2 in the reference example illustrated in FIG. 3 includes a resistor 100 instead of the third circuit 20 in the signal transmission circuit 1 illustrated in FIG. 1. Since the other components are the same as the components of the electronic device 1000 in the first embodiment, the same components as the components of the electronic device 1000 in the first embodiment are denoted by the same reference numerals and signs and explanation of the components is omitted. The resistance value of the resistor 100 is 50Ω. That is, in the reference example, the characteristic impedance of the second transmission line 14 and the resistance value of the resistor 100 are equal. Accordingly, in the reference example, reflection of a signal does not occur in the resistor 100. All the signal input to the fourth transmission line 16 flows to the body ground 22 and the housing ground 23.

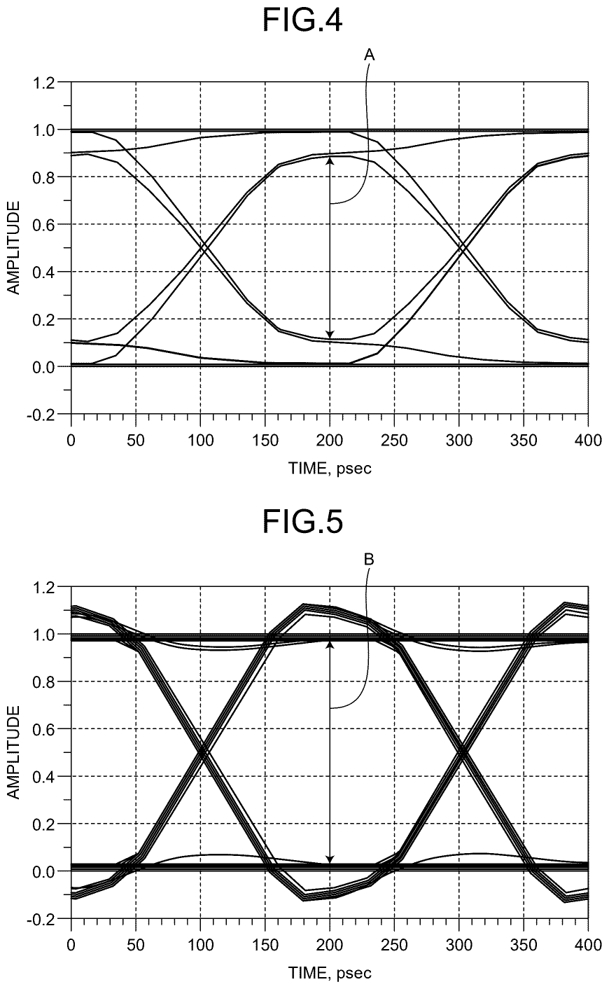

FIG. 4 is a simulation result of an eye pattern of a signal passing through the coaxial cable 3000 in the reference example illustrated in FIG. 3.

FIG. 5 is a simulation result of an eye pattern of a signal passing through the coaxial cable 3000 in the present embodiment illustrated in FIG. 1.

In FIG. 4 and FIG. 5, the horizontal axis represents time and the vertical axis represents amplitude (a relative value).

Amplitude A in FIG. 4 indicates the magnitude of the amplitude of the eye pattern at 200 psec.

Amplitude B in FIG. 5 indicates the magnitude of the amplitude of the eye pattern at 200 psec.

In the eye pattern, the larger amplitude indicates that the strength of the signal is higher. When the amplitude A and the amplitude B are compared, it can be seen that the amplitude is larger and the strength of the signal is higher in the present embodiment in which reflection of the signal in the third circuit 20 occurs than in the reference example in which reflection of the signal in the resistor 100 does not occur. For that reason, compared with the reference example, in the present embodiment, since the strength of the signal passing through the coaxial cable 3000, that is, output from the electronic device 1000 is high, the possibility that the signal cannot be detected in the electronic device 2000 can be reduced.

As explained above, the signal transmission circuit 1 in the present embodiment includes the common mode filter 12 including the first inductor 121 and the second inductor 122, the first circuit 18 including the first capacitor 181, the second circuit 19 including the second capacitor 191 and having the same circuit configuration as the first circuit 18, the third circuit 20 having a circuit configuration different from the second circuit 19, the third circuit 20 including the input end 201 and the output end 202, reflecting a predetermined amount of a signal in a predetermined frequency band including the frequency of a transmission signal in a signal input thereto, and allowing another component to pass, the first transmission line 13 having one end connected to the communication circuit 11 which outputs a differential signal, and having the other end connected to one end of the first inductor 121 via the first circuit 18, the second transmission line 14 having one end connected to the communication circuit 11, and having the other end connected to one end of the second inductor 122 via the second circuit 19 and having characteristic impedance different from the impedance of the third circuit 20, the third transmission line 15 connected to the other end of the first inductor 121 and the output terminal 21, the fourth transmission line 16 connected to the other end of the second inductor 122 and the input end 201, and the fifth transmission line 17 connected to the output end and the ground.

With such a configuration, the signal transmission circuit 1 in the present embodiment can improve the strength of a signal to be transmitted.

### Second Embodiment

A second embodiment of an electronic device according to the present disclosure is explained below with reference to the drawings.

The electronic device 1200 in the present embodiment includes, between the fourth transmission line 16 and the fifth transmission line 17, a fourth circuit 24 in addition to the third circuit 20 in the first embodiment. In the present embodiment, the resistance value of the first resistor 203 and the capacitance of the third capacitor 204 are different from those in the first embodiment. Since the other components are the same as the components of the electronic device 1000 in the first embodiment, the same components as the components of the electronic device 1000 in the first embodiment are denoted by the same reference numerals and signs and explanation of the components is omitted.

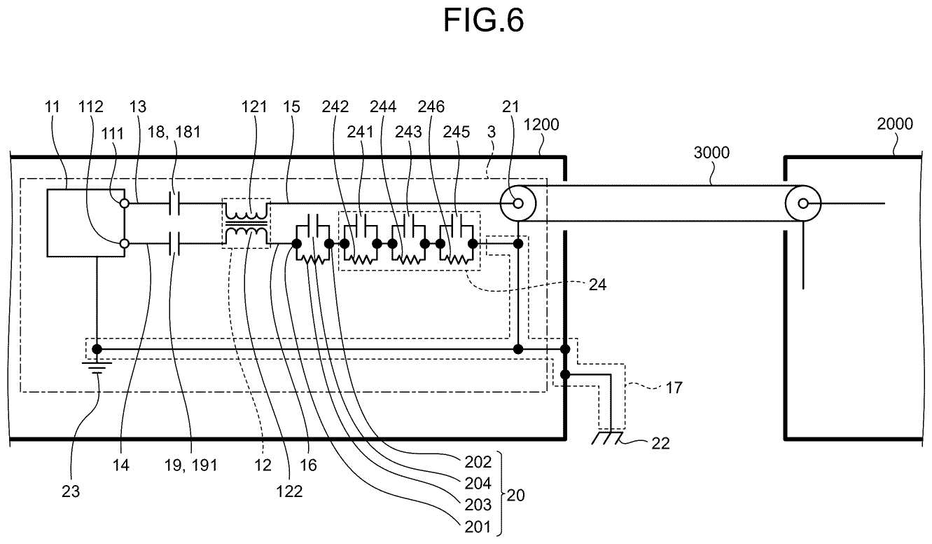

FIG. 6 is a schematic diagram of a configuration of the electronic device 1200. As illustrated in FIG. 5, the electronic device 1200 includes a signal transmission circuit 3. The signal transmission circuit 3 includes the fourth circuit 24 connected in series between the output end 202 and the fifth transmission line 17.

The third circuit 20 includes the first resistor 203 and the third capacitor 204 connected to first resistor 203 in parallel.

The fourth circuit 24 includes a second resistor 241 and a fourth capacitor 242 connected to the second resistor 241 in parallel. The fourth circuit 24 may have a configuration in which the fourth circuit 24 further includes a third resistor 243, a fifth capacitor 244 connected to the third resistor 243 in parallel, a fourth resistor 245, and a sixth capacitor 246 connected to the fourth resistor 245 in parallel and the parallel connection of the second resistor 241 and the fourth capacitor 242, the parallel connection of the third resistor 243 and the fifth capacitor 244, and the parallel connection of the fourth resistor 245 and the sixth capacitor 246 are connected in series in this order. An example of the configuration is explained below.

In the present embodiment, the capacitances of the third capacitor 204, the fourth capacitor 242, the fifth capacitor 244, and the sixth capacitor 246 are different from one another. As an example, in the present embodiment, the capacitance of the third capacitor 204 is 100 pF, the capacitance of the fourth capacitor 242 is 10 pF, the capacitance of the fifth capacitor 244 is 1 pF, and the capacitance of the sixth capacitor 246 is 0.1 pF. As an example, in the present embodiment, all of the resistance values of the first resistor 203, the second resistor 241, the third resistor 243, and the fourth resistor 245 are 12.5Ω.

In the following explanation, the third circuit 20 and the fourth circuit 24 are collectively regarded as one circuit and referred to as fifth circuit. In the present embodiment, the impedance of the fifth circuit is determined by the resistance values of the first resistor 203, the second resistor 241, the third resistor 243, and the fourth resistor 245, the capacitances of the third capacitor 204, the fourth capacitor 242, the fifth capacitor 244, and the sixth capacitor 246, and the frequency of a signal input to the fifth circuit.

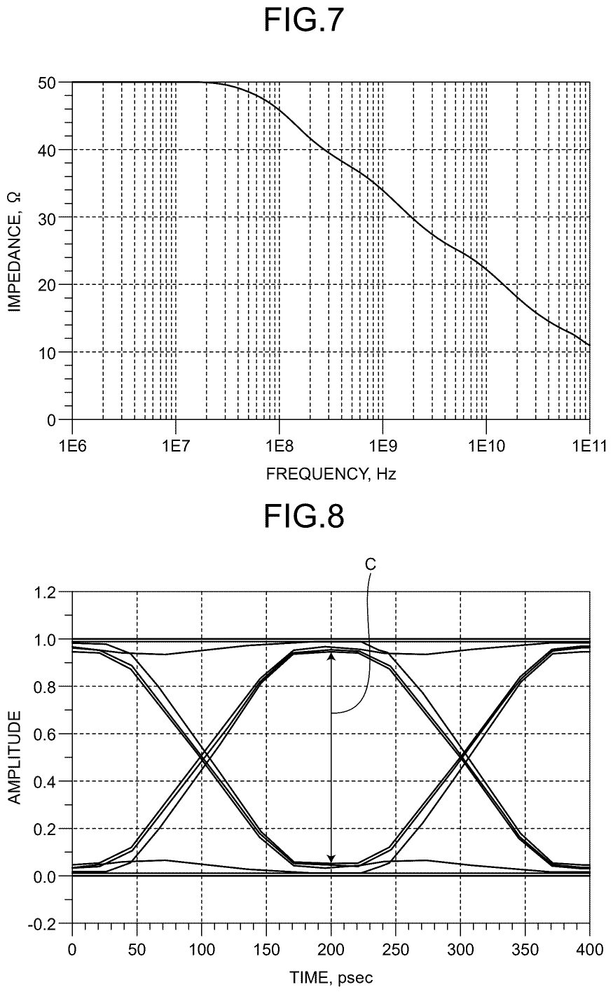

FIG. 7 is a simulation result indicating a relation between the frequency of the signal input to the fifth circuit and the impedance of the fifth circuit in the present embodiment.

In FIG. 7, the horizontal axis represents the frequency of the signal input to the fifth circuit and the vertical axis represents the impedance of the fifth circuit.

When a signal having a frequency lower than the decrease start frequency is input, the impedance of the fifth circuit coincides with the sum of the resistance values of the first resistor 203, the second resistor 241, the third resistor 243, and the fourth resistor 245. Therefore, as illustrated in FIG. 7 as well, the impedance of the fifth circuit in the case in which the signal having the frequency lower than the decrease start frequency is input is 50Ω. The resistance values of the resistors may be set as appropriate such that the characteristic impedance of the second transmission line 14 and the impedance of the fifth circuit in the case in which the signal having the frequency lower than the decrease start frequency is input are equal.

According to FIG. 7, it is seen that the impedance of the fifth circuit is lower as the frequency of the signal input to the fifth circuit is higher.

In the present embodiment, the decrease start frequency is determined by the capacitances of the first resistor 203, the second resistor 241, the third resistor 243, the fourth resistor 245, the third capacitor 204, the fourth capacitor 242, the fifth capacitor 244, and the sixth capacitor 246. Here, in the present embodiment, in order to match the impedance of the fifth circuit in the case in which the signal having the frequency lower than the decrease start frequency is input and the characteristic impedance of the second transmission line 14, the sum of the resistance values of the resistors is fixed to 50Ω. For that reason, when the decrease start frequency is changed, the capacitance of at least one of the capacitors is changed. When the capacitance of at least one of the capacitors is increased, the decrease start frequency decreases. When the capacitance of at least one of the capacitors is decreased, the decrease start frequency is increased.

As an example, by increasing the capacitances of the capacitors respectively at the same ratio, it is possible to reduce the decrease start frequency without changing an amount of change in the impedance of the fifth circuit with respect to an amount of change in the frequency of the signal input to the fifth circuit in the case in which the signal having the frequency higher than the decrease start frequency is input. Similarly, by reducing the capacitances of the capacitors respectively at the same ratio, it is possible to increase the decrease start frequency without changing the amount of change in the impedance of the fifth circuit with respect to the amount of change in the frequency of the signal input to the fifth circuit in the case in which the signal having the frequency higher than the decrease start frequency is input. The capacitances of the capacitors may be set as appropriate such that a desired decrease start frequency can be obtained.

As explained above, also in the present embodiment in which a high-frequency signal of 100 MHz or more is transmitted as in the first embodiment, the characteristic impedance of the second transmission line 14 and the impedance of the fifth circuit are different. Accordingly, the fifth circuit can reflect the fifth signal that is a part of the fourth signal. Accordingly, since the seventh signal is generated in the second inductor 122, the energy of the seventh signal can be added to the third signal. For that reason, the strength of the signal output from the electronic device 1000 can be improved.

When FIG. 2 and FIG. 7 are compared, it is seen that the amount of change in the impedance of the fifth circuit with respect to the amount of change in the frequency of the signal input to the fifth circuit is small in FIG. 7. Depending on the performance of the coaxial cable 3000, since the attenuation amount of the energy of the third signal is small, the amount of the signal reflected by the third circuit 20 or the fourth circuit 24 may be small in some case. In such a case, as in the present embodiment, the number of parallel connections of the resistors and the capacitors provided between the fourth transmission line 16 and the fifth transmission line 17 is set to plural and the capacitances of the capacitors are set different from one another. Therefore, it is possible to prevent the impedance from greatly decreasing even when a signal having a high frequency is input. Accordingly, the amount of the signal reflected by the fifth circuit can be reduced. Note that, as the number of parallel connections of the resistors and the capacitors provided between the fourth transmission line 16 and the fifth transmission line 17 is increased, it is possible to reduce the amount of change in the impedance of the fifth circuit with respect to the amount of change in the frequency of the signal input to the fifth circuit. for that reason, the number of parallel connections of the resistors and the capacitors may be determined by the performance of the coaxial cable 3000. In the present embodiment, the number of parallel connections of the resistors and the capacitors is four. However, depending on the performance of the coaxial cable 3000, the number of parallel connections of the resistors and the capacitors may be two or three or may be five or more.

FIG. 8 is a simulation result of an eye pattern of a signal passing through the coaxial cable 3000 illustrated in FIG. 1 illustrating a schematic configuration in the present embodiment. In FIG. 8, the horizontal axis represents time and the vertical axis represents amplitude (a relative value).

Amplitude C in FIG. 8 indicates the magnitude of the amplitude of an eye pattern at 200 psec.

When the amplitude C and the amplitude A in FIG. 4 illustrating the simulation result of the eye pattern in the reference example are compared, it is seen that the amplitude of the eye pattern is larger and the strength of the signal is higher in the present embodiment in which reflection of the signal on the fifth circuit occurs than in the reference example in which reflection of the signal in the resistor 100 does not occur. For that reason, compared with the reference example, in the present embodiment, since the strength of the signal passing through the coaxial cable 3000, that is, output from the electronic device 1000 is high, the possibility that the signal cannot be detected in the electronic device 2000 can be reduced.

When FIG. 8 and FIG. 5 illustrating the simulation result of the eye pattern in the first embodiment are compared, in FIG. 8, since an amount of reflection of a signal having a frequency other than a desired frequency is small, the upper end of the amplitude of the eye pattern at 200 psec is closer to 1.0 and the lower end of the amplitude is closer to 0.0. That is, in the present embodiment, compared with the first embodiment EMC (Electro Magnetic Compatibility) performance is better and it is possible to reduce a possibility of emitting noise to the outside.

According to the present disclosure, the strength of a signal to be transmitted can be improved.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

The effects of the embodiments described in the present specification are merely examples and are not limiting. Other effects may be present.

### Notes

An aspect of the present disclosure is as follows.

### First Aspect

A signal transmission circuit including:
a common mode filter including a first inductor and a second inductor;
a first circuit including a first capacitor;
a second circuit including a second capacitor and having a same circuit configuration as the first circuit;
a third circuit that includes an input end and an output end, has a circuit configuration different from the second circuit, reflects a predetermined amount of a signal in a predetermined frequency band including a frequency of a transmission signal in a signal input thereto, and allows another component to pass;
a first transmission line having one end connected to a communication circuit that outputs a differential signal, and having another end connected to one end of the first inductor via the first circuit;
a second transmission line having one end connected to the communication circuit, and having another end connected to one end of the second inductor via the second circuit and having characteristic impedance different from impedance of the third circuit;
a third transmission line connected to another end of the first inductor and an output terminal;
a fourth transmission line connected to another end of the second inductor and the input end; and
a fifth transmission line connected to the output end and a ground or an earth.

According to this aspect, the energy of a signal reflected by the third circuit can be added to a signal that flows to a coaxial cable via the third transmission line and in which energy is attenuated. Accordingly, the strength of a signal to be transmitted can be improved.

### Second Aspect

The signal transmission circuit according to First Aspect, wherein
the impedance of the third circuit is smaller than the characteristic impedance of the second transmission line.

According to this aspect, a part of the signal input to the third circuit can be reflected to the second inductor.

### Third Aspect

The signal transmission circuit according to First Aspect or Second Aspect, wherein
the third circuit includes a first resistor and a third capacitor connected to the first resistor in parallel.

According to this aspect, a part of the signal input to the third circuit can be reflected to the second inductor.

### Fourth Aspect

The signal transmission circuit according to Third Aspect, further including
a fourth circuit connected in series between the output end and the ground or the earth, wherein
the fourth circuit includes a second resistor and a fourth capacitor connected to the second resistor in parallel.

According to this aspect, amounts of changes in the impedances of the third circuit and the fourth circuit with respect to amounts of changes in the frequencies of signals input to the third circuit and the fourth circuit can be reduced. Accordingly, it is possible to reduce a possibility of reflecting a signal having magnitude larger than necessary.

### Fifth Aspect

The signal transmission circuit according to Fourth Aspect, wherein
capacitance of the third capacitor and capacitance of the fourth capacitor are different.

According to this aspect, amounts of changes in the impedances of the third circuit and the fourth circuit with respect to amounts of changes in the frequencies of signals input to the third circuit and the fourth circuit can be reduced. Accordingly, it is possible to reduce a possibility of reflecting a signal having magnitude larger than necessary.

### Sixth Aspect

The signal transmission circuit according to any one of First Aspect to Fifth Aspect, wherein
characteristic impedance of the first transmission line and the characteristic impedance of the second transmission line are equal.

According to this aspect, common mode noise less easily occurs in respective signals passing through the first transmission line and the second transmission line.

### Seventh Aspect

The signal transmission circuit according to any one First Aspect to Sixth Aspect, wherein
the first circuit includes only the first capacitor,
the second circuit includes only the second capacitor, and
capacitance of the first capacitor and capacitance of the second capacitor are equal.

According to this aspect, common mode noise less easily occurs in respective signals passing through the first transmission line and the second transmission line.

### Eighth Aspect

The signal transmission circuit according any one of First Aspect to Seventh Aspect, further including the communication circuit.

According to this aspect, since the length of a transmission line can be shortened compared with the case in which a communication circuit is provided on the outside of the signal transmission circuit, an attenuation amount of the energy of a signal flowing through the transmission line can be reduced. It is possible to reduce a possibility that noise occurs in the signal flowing through the transmission line.

### Ninth Aspect

An electronic device including the signal transmission circuit according to any one of First Aspect to Eighth Aspect.

According to this aspect, the energy of a signal reflected by the third circuit can be added to a signal that flows to a coaxial cable via the third transmission line and in which energy is attenuated. Accordingly, the strength of a signal to be transmitted can be improved.

What is claimed is:

1. A signal transmission circuit comprising:
a common mode filter including a first inductor and a second inductor;
a first circuit including a first capacitor;
a second circuit including a second capacitor and having a same circuit configuration as the first circuit;
a third circuit that includes an input end and an output end, has a circuit configuration different from the second circuit, reflects a predetermined amount of a signal in a predetermined frequency band including a frequency of a transmission signal in a signal input thereto, and allows another component to pass;
a first transmission line having one end connected to a communication circuit that outputs a differential signal, and having another end connected to one end of the first inductor via the first circuit;
a second transmission line having one end connected to the communication circuit, and having another end connected to one end of the second inductor via the second circuit and having characteristic impedance different from impedance of the third circuit;
a third transmission line connected to another end of the first inductor and an output terminal;
a fourth transmission line connected to another end of the second inductor and the input end; and
a fifth transmission line connected to the output end and a ground or an earth.

2. The signal transmission circuit according to claim 1, wherein
the impedance of the third circuit is smaller than the characteristic impedance of the second transmission line.

3. The signal transmission circuit according to claim 1, wherein
the third circuit includes a first resistor and a third capacitor connected to the first resistor in parallel.

4. The signal transmission circuit according to claim 3, further comprising
a fourth circuit connected in series between the output end and the ground or the earth, wherein
the fourth circuit includes a second resistor and a fourth capacitor connected to the second resistor in parallel.

5. The signal transmission circuit according to claim 4, wherein
capacitance of the third capacitor and capacitance of the fourth capacitor are different.

6. The signal transmission circuit according to claim 1, wherein
characteristic impedance of the first transmission line and the characteristic impedance of the second transmission line are equal.

7. The signal transmission circuit according to claim 1, wherein
the first circuit includes only the first capacitor,
the second circuit includes only the second capacitor, and
capacitance of the first capacitor and capacitance of the second capacitor are equal.

8. The signal transmission circuit according to claim 1, further comprising
the communication circuit.

9. An electronic device comprising the signal transmission circuit according to claim 1.
